(19) United States
(12) Patent Application Publication
(10) Pub. No.: US 2026/0045438 A1
(43) Pub. Date: Feb. 12, 2026

(54) APPARATUS AND METHOD FOR IMPROVED ELECTRON MULTI-BEAM INSPECTION

(71) Applicant: Taiwan Semiconductor Manufacturing Company, Ltd., Hsinchu (TW)

(72) Inventors: Xiaomeng CHEN, Hsinchu (TW); Ding-Shiun TU, Hsinchu (TW); Kuang-Shing CHEN, Hsinchu (TW); Chien-Li WU, Hsinchu (TW)

(73) Assignee: Taiwan Semiconductor Manufacturing Company, Ltd., Hsinchu (TW)

(21) Appl. No.: 19/018,145

(22) Filed: Jan. 13, 2025

Related U.S. Application Data
(60) Provisional application No. 63/682,132, filed on Aug. 12, 2024.

(51) Int. Cl. H01J 37/09

(52) U.S. Cl. CPC H01J 37/09; H01J 2237/0453; H01J 2237/0492; H01J 2237/2505

(57) ABSTRACT

A method of performing an electron multi-beam inspection of a semiconductor substrate includes generating a primary electron beam; focusing the primary electron beam to generate a focused electron beam including an optimized beam illumination area; generating sub-beams from the focused electron beam by causing the focused electron beam to impinge on a beam splitter such that the optimized beam illumination area is smaller than a total area of the beam splitter; and blocking a first plurality of the sub-beams by causing the sub-beams to impinge on a mask including a blocking area and an open area, such that a second plurality of the sub-beams passes through the mask, wherein the open area is located within the optimized beam illumination area. According to various embodiments, the method further includes dynamically controlling a size and shape of the blocking area and the open area by controlling the plurality of MEMS shutters.

### CROSS-REFERENCE TO RELATED APPLICATION

This application claims priority to U.S. Provisional Patent Application No. 63/682,132, filed on Aug. 12, 2024, the disclosure of which is incorporated herein by reference in its entirety.

### BACKGROUND

In the field of semiconductor device manufacturing, as circuit patterns become increasingly intricate, the need for high-resolution inspection systems to accurately detect and address defects becomes more pronounced. Electron multi-beam inspection systems offer a promising approach for high-resolution inspection and defect detection. These systems provide methods for analyzing intricate patterns, such as those formed using EUV lithography, enabling rapid and precise identification of nanometer-scale defects. This facilitates improved yield and performance in semiconductor devices.

### BRIEF DESCRIPTION OF THE DRAWING

The present disclosure is best understood from the following detailed description when read with reference to the accompanying figures. It is emphasized that, following the standard practice in the industry, various features are not drawn to scale and are used for illustration purposes only. In this regard, the dimensions of the various features may be arbitrarily increased or reduced for clarity of discussion.

FIG. 1 is a vertical cross-sectional view of an EUV lithography system, according to various embodiments.

FIG. 2 is a vertical cross-sectional view of an electron-beam inspection system, according to various embodiments.

FIG. 3A is a top view of a beam splitter configured as an aperture array, according to various embodiments.

FIG. 3B is a top view of a mask having a blocking area and an open area, according to various embodiments.

FIG. 4A is a top view of a beam splitter with a focused electron beam impinging on an optimized beam illumination area, according to various embodiments.

FIG. 4B is a top view of a beam splitter with a focused electron beam impinging on an optimized beam illumination area, according to various embodiments.

FIG. 4C is a top view of a beam splitter with a focused electron beam impinging on an optimized beam illumination area, according to various embodiments.

FIG. 5A is a top view of a mask having a reconfigurable shutter system in a first configuration, according to various embodiments.

FIG. 5B is a top view of the mask of FIG. 5A in a second configuration, according to various embodiments.

FIG. 6 is a schematic view of an electron-beam inspection system including a reconfigurable multi-mask device having a plurality of selectable masks, according to various embodiments.

FIG. 7 is a flowchart illustrating operations of a method of performing an electron multi-beam inspection of a semiconductor substrate, according to various embodiments.

### DETAILED DESCRIPTION

The following disclosure provides many different embodiments, or examples, for implementing different features of the provided subject matter. Specific examples of components and arrangements are described below to simplify this disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, this disclosure may repeat reference numerals and/or letters in the various examples. This repetition is for simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “made of” may mean either “including” or “consisting of.” In this disclosure, the phrase “one of A, B and C” means “A, B and/or C” (A, B, C, A and B, A and C, B and C, or A, B and C), and does not mean one element from A, one element from B and one element from C, unless otherwise described.

Disclosed embodiments are advantageous by providing systems and methods of performing electron multi-beam inspection of a semiconductor substrate with increased signal quality and increased throughput. In this regard, a method includes focusing a primary electron beam to generate a focused electron beam having an optimized beam illumination area. The focused electron beam is then caused to impinge on a beam splitter such that the optimized beam illumination area is smaller than a total area of the beam splitter. As such, electron sub-beams generated by the beam splitter are directed only into areas tightly surrounding a region of interest corresponding to a circuit element to be scanned. The electron current in individual sub-beams is thereby increased by focusing the optimized electron beam in this way. A mask is also used to block sub-beams from regions other than the region of interest. This blocking reduces unwanted signals from areas outside of the region of interest and thereby increases the performance of electron multi-beam inspection systems.

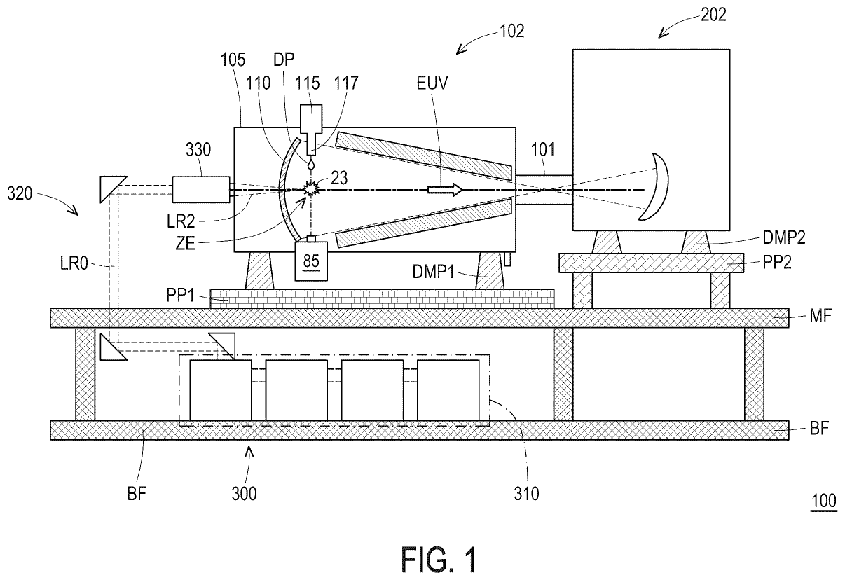

FIG. 1 is a vertical cross-sectional view of an extreme ultraviolet (EUV) lithography system 100 with an EUV radiation source 102, according to various embodiments. The EUV lithography system 100 further includes an exposure device 202, such as a scanner, and an excitation laser source 300. As shown in FIG. 1, in some embodiments, the EUV radiation source 102 and the exposure device 202 are installed on a main floor MF of a clean room, while the excitation laser source 300 is installed in a base floor BF located under the main floor. Each of the EUV radiation source 102 and the exposure device 202 are placed over pedestal plates PP1 and PP2 via dampers DMP1 and DMP2, respectively. The EUV radiation source 102 and the exposure device 202 are coupled to one another by a coupling mechanism, which includes a focusing unit 101.

The EUV lithography system 100 is designed to expose a resist layer, formed over a substrate, to EUV radiation. The resist layer is a material sensitive to the EUV radiation. The EUV lithography system 100 employs the EUV radiation source 102 to generate EUV radiation, such as EUV radiation having a wavelength ranging between about 1 nm and about 50 nm. In an example embodiment, the EUV radiation source 102 generates EUV radiation with a peak wavelength that is approximately 13.5 nm. In this embodiment, the EUV radiation source 102 utilizes a mechanism of laser-produced plasma to generate the EUV radiation.

The exposure device 202 includes various reflective optical components, such as convex mirrors, concave mirrors, and flat mirrors. The exposure device 202 further includes a mask-holding mechanism including a mask stage, and a wafer-holding mechanism (e.g., a substrate holding mechanism). The EUV radiation generated by the EUV radiation source 102 is guided by the reflective optical components onto a mask secured on the mask stage (both not shown in FIG. 1). In some embodiments, the mask stage includes an electrostatic chuck (e-chuck) to secure the mask. Because gas molecules absorb EUV radiation, the EUV lithography system 100 is maintained in a vacuum or a low-pressure environment to avoid EUV intensity loss.

In this disclosure, the terms “mask,” “photomask,” and “reticle” are used interchangeably. In addition, the terms “resist” and “photoresist” are used interchangeably. EUV radiation emitted by the EUV radiation source 102 is directed by optical components to project a mask pattern of the mask onto the photoresist layer of the substrate. In some embodiments, the mask is reflective.

In various embodiments, the semiconductor substrate is a semiconductor wafer, such as a silicon wafer or other type of wafer to be patterned. The semiconductor substrate is coated with a resist layer that is sensitive to the EUV radiation. Various components, including those described above, are integrated and are operable to perform lithography exposure processes. The EUV lithography system 100 may further include other modules or be integrated with (or be coupled with) other modules, according to various embodiments.

As shown in FIG. 1, the EUV radiation source 102 includes a droplet generator 115 and a laser-produced plasma collector mirror 110, enclosed by a chamber 105. The droplet generator 115 generates a plurality of target droplets DP, which are supplied into the chamber 105 through a nozzle 117. In some embodiments, the target droplets DP are Sn, Li, or an alloy of Sn and Li. In some embodiments, the target droplets DP each have a diameter in a range from about 10 microns to about 102 microns.

The excitation laser beam LR2 generated by the excitation laser source 300 is a pulsed beam. The laser pulses of laser beam LR2 are generated by the excitation laser source 300. The excitation laser source 300 includes a laser generator 310, laser guide optics 320, and a focusing apparatus 330. In some embodiments, the laser generator 310 includes a carbon dioxide (CO₂) or a neodymium-doped yttrium aluminum garnet (Nd: YAG) laser source with a wavelength in the infrared region of the electromagnetic spectrum. For example, the laser source 310 has a wavelength of 9.4 microns or 10.6 microns in an embodiment. The laser beam LR0 generated by the excitation laser source 300 is guided by the laser guide optics 320 and focused, by the focusing apparatus 330, into the excitation laser beam LR2 that is introduced into the EUV radiation source 102. In some embodiments, in addition to CO₂ and Nd: YAG lasers, the laser beam LR2 is generated by a gas laser including an excimer gas discharge laser, helium-neon laser, nitrogen laser, transversely excited atmospheric (TEA) laser, argon ion laser, copper vapor laser, KrF laser or ArF laser; or a solid state laser including Nd: glass laser, ytterbium-doped glasses or ceramics laser, or ruby laser. In some embodiments, a non-ionizing laser beam (not shown) is also generated by the excitation laser source 300 and the non-ionizing laser beam is also focused by the focusing apparatus 330.

The laser beam LR2 is directed through windows or lenses (not shown) into the zone of excitation ZE. The windows or lenses may be made of a suitable material that is substantially transparent to the laser beams. The generation of the laser pulses is synchronized with the ejection of the target droplets DP through the nozzle 117. As the target droplets move through the excitation zone, the pre-pulses heat the target droplets and transform them into low-density target plumes. A delay between the pre-pulse and the main pulse is controlled to allow the target plume to form and expand to an optimal size and geometry. In various embodiments, the pre-pulse and the main pulse have the same pulse duration and peak power. When the main pulse heats the target plume, a high-temperature plasma is generated. The plasma emits EUV radiation, which is collected by the collector mirror 110. The collector mirror 110, which is configured as an EUV collector mirror, further reflects, and focuses the EUV radiation which may be provided to the exposure device 202. A droplet DP that does not interact with the laser pulses is captured by the droplet catcher 85.

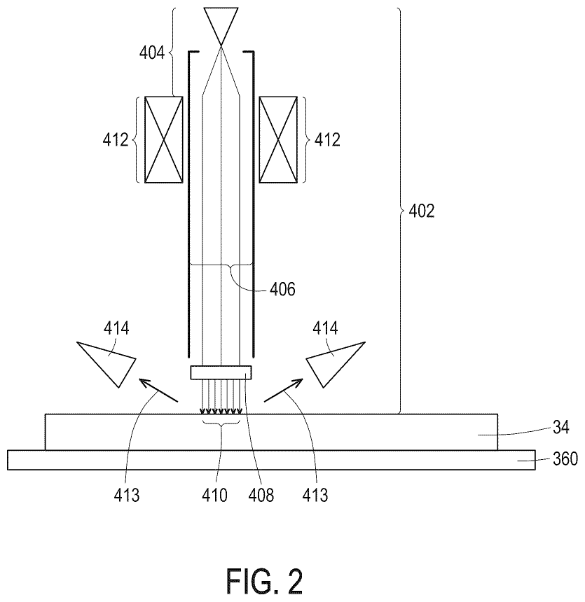

FIG. 2 is a vertical cross-sectional view of an electron-beam inspection system 402, according to various embodiments. The electron-beam inspection system 402 is configured as an electron multi-beam inspection system. The electron-beam inspection system 402 includes an electron source 404 (e.g., an “electron gun”) configured to generate a primary electron beam 406. The electron-beam inspection system 402 further includes a beam splitter 408 that is configured to generate sub-beams 410 from the primary electron beam 406. As shown, the sub-beams 410 are directed at the semiconductor device 34 (such as a wafer having circuit elements formed therein).

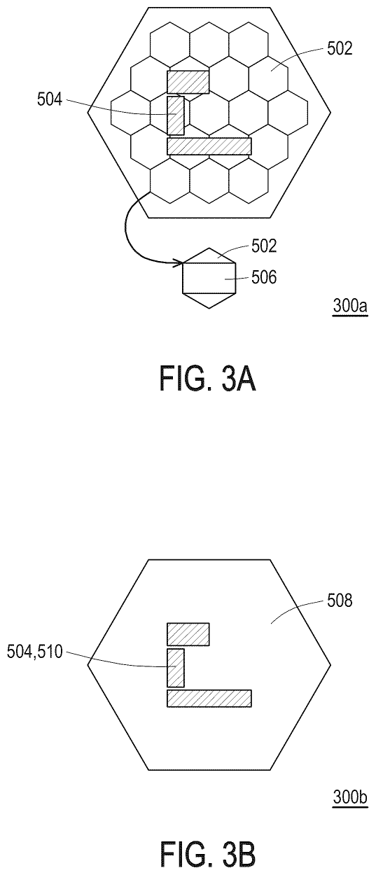

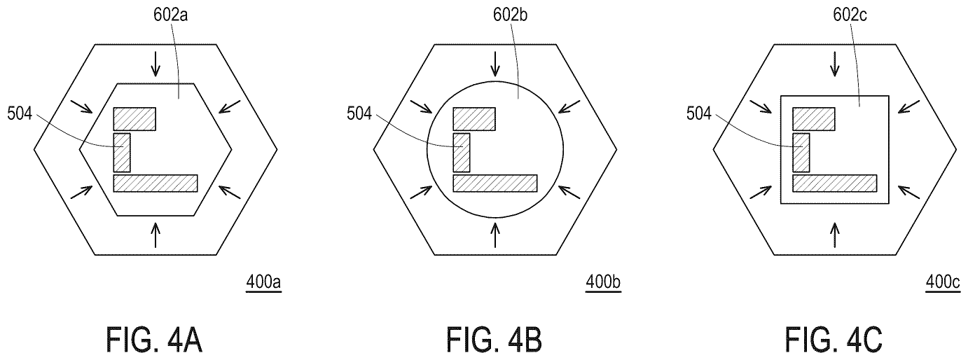

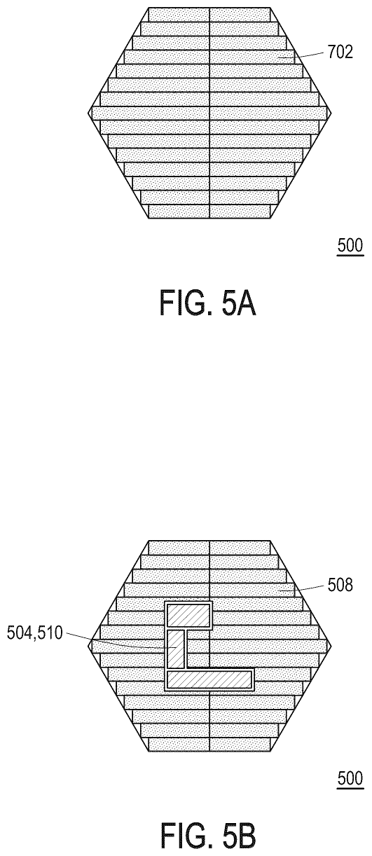

The electron-beam inspection system 402 further includes a focusing device 412 configured to focus the primary electron beam 406 on an optimized sub-area of the beam splitter 408. As described in greater detail below (e.g., with reference to FIGS. 3A to 4C) electron beam current is increased and system performance is improved by focusing the primary electron beam 406 on an optimized sub-area of the beam splitter 408 (i.e., an area that is less than a total area of the beam splitter 408) thereby reducing a number of sub-beams 410 that would otherwise be directed to featureless regions of the semiconductor device 34. According to various embodiments, the electron-beam inspection system 402 further includes a mask (300b, 500) (see FIGS. 3B, 5A, and 5B) having a blocking area 508 configured to block a first plurality of the sub-beams 410 and an open area 510 configured to allow a second plurality of the sub-beams 410 to pass through the mask (300b, 500), as described in greater detail below.

In some embodiments, the electron-beam inspection system 402 is coupled with the EUV lithography system 100, but in other embodiments, the electron-beam inspection system 402 may operate as a stand-alone unit at various stages along a semiconductor fabrication processing line. When coupled with the EUV lithography system 100, different approaches are used depending on the specific design and requirements of the semiconductor manufacturing line, according to various embodiments. For example, in some embodiments, the electron-beam inspection system 402 is not installed in the same vacuum chamber as the EUV patterning module but rather in a separate inspection module. However, in such embodiments, the process is configured to ensure efficient wafer transfer between the EUV lithography tool 100 and the electron-beam inspection system 402, either maintaining vacuum or allowing for controlled venting.

According to various embodiments, the wafer is transferred from the EUV exposure device 202, or another module in the processing line, to the electron-beam inspection system 402 without breaking vacuum. This configuration is advantageous because it minimizes the risk of contamination, where even small particles can significantly impact yield due to the fine feature sizes being patterned. A vacuum-based wafer handling system ensures that the environment remains free from contaminants during the transfer process. This can be achieved by integrating vacuum-compatible robotic handling systems (not shown) that shuttle wafers between the EUV lithography tool 100, or other modules in the processing line, and the electron-beam inspection system 402 through vacuum-tight load locks.

Alternatively, in some embodiments, the wafer is transferred to the multibeam inspection system 402 with a controlled venting process, where the vacuum is broken temporarily but under highly controlled conditions to prevent contamination. In such cases, the chambers are purged with clean gases, and the time spent outside of vacuum is minimized to reduce the possibility of particulate or chemical contamination. The decision on whether to maintain vacuum or allow for controlled venting during wafer transfer depends on the specific design goals of the semiconductor fabrication line, the criticality of contamination control, and throughput considerations. Maintaining vacuum throughout the process may be implemented in high-end manufacturing environments, as it enhances cleanliness and reduces the potential for yield loss due to defects introduced during handling. However, both configurations can be successfully implemented, with the multibeam inspection system 402 integrated as an important tool for defect detection in various stages of semiconductor device manufacturing operations.

As shown in FIG. 2, when the electron beams (i.e., sub-beams 410) interact with the material of the semiconductor device 34, signals 413 such as secondary electrons, backscattered electrons, or X-rays are generated (e.g., see FIG. 2). These signals are collected by detectors 414 and analyzed to identify features or irregularities on the semiconductor device 34. The multi-beam approach enables increased inspection speed and throughput compared to single-beam systems while maintaining the ability to achieve detailed, high-resolution imaging. The electron-beam inspection system 402 is configured to support automated defect detection and classification, making it desirable for use in high-volume semiconductor manufacturing processes. The system is adaptable for inspecting complex structures and geometries, which is advantageous as feature sizes continue to shrink with advancing semiconductor technology nodes.

Based on the information provided by the electron-beam inspection system 402, various corrective follow-up actions are implemented, in various embodiments, to address defects and optimize the semiconductor manufacturing process, ultimately enhancing yield and device quality. One step involves defect classification and root cause analysis, where detailed data about the type, size, and location of defects allows engineers to determine the source of issues such as contamination, lithography misalignment, or process variations. This leads to targeted corrective actions, in certain embodiments, such as process adjustments.

In this regard, the data can be used to optimize process parameters for future batches. For example, adjustments to EUV lithography settings like exposure dose or mask alignment may be necessary if consistent defects, such as line-width variations, are detected. Furthermore, the system's insights can drive yield improvement strategies by highlighting tools or process steps that are contributing to defect generation, prompting actions like more frequent mask cleaning or changes in process control protocols.

The use of multiple beams (i.e., sub-beams 410) in an electron multi-beam inspection system (such as the electron-beam inspection system 402) offers several advantages that enhance the efficiency and effectiveness of semiconductor manufacturing processes. One of the primary reasons for employing multiple beams is the increased throughput, as this approach enables the inspection of larger areas of the semiconductor device 34 simultaneously. By splitting the primary electron beam 406 into multiple sub-beams 410, the system 402 can cover more surface area in the same amount of time compared to single beam inspections, which is particularly valuable in high-volume manufacturing environments where rapid inspections are essential for maintaining production efficiency. The parallel processing nature of multiple beams also facilitates more comprehensive data collection during inspections, enabling simultaneous imaging and analysis. This parallelism accelerates the inspection process and allows for more detailed and accurate assessments of the wafer surface.

Moreover, leveraging multiple beams significantly reduces overall inspection time, which is important in semiconductor manufacturing, as inspection delays can lead to production bottlenecks. Faster inspections provide quicker feedback on manufacturing processes, enabling timely adjustments to maintain quality control. Utilizing multiple beams also offers flexibility in inspection techniques, allowing various imaging modalities, such as high-resolution imaging, dark field imaging, or defect classification, to be employed simultaneously. Collectively, these benefits contribute to more efficient and effective semiconductor manufacturing processes, ultimately resulting in higher-quality products.

The electron-beam inspection system 402 includes several components that work together to enable high-resolution and efficient inspection of semiconductor wafers. As described above, the system 402 includes an electron source 404 that generates a stable, high-intensity primary electron beam 406, which is divided into multiple sub-beams 410 by the beam splitter 408. This beam splitter 408 works with an optics system (e.g., including the focusing device 412). The optics system includes electromagnetic lenses and apertures, which focus and control the paths of the individual beams, ensuring that each beam is properly aligned and focused on the semiconductor device 34.

A scanning system directs the beams across the semiconductor device 34 using electrostatic or electromagnetic deflectors, enabling complete surface coverage during the inspection. The semiconductor device 34 is positioned on a movable stage 360 capable of precise X-Y motion, motorized and controlled by feedback systems in some embodiments to ensure accurate alignment throughout the process. Detectors 414, positioned strategically around the system 402, collect signals 413 such as secondary electrons or backscattered electrons, which are produced when the electron beams interact with the semiconductor device 34. These signals 413 are processed to create high-resolution images that reveal defects or surface irregularities.

The system 402 also includes a data processing and control unit (not shown) that analyzes the collected signals 413 and coordinates the electron source 404, optics 412, scanning system, and stage 360 to ensure precise and synchronized operation. To prevent scattering of the electron beams 410, the inspection is conducted inside a vacuum chamber (not shown), which provides a controlled environment for optimal beam stability and imaging resolution. Together, these components allow the system to efficiently inspect wafers (e.g., substrate (10, 210) and semiconductor device 34), thereby meeting the stringent requirements of semiconductor manufacturing processes.

The focusing device 412 is one component of an optics system that works in conjunction with the beam splitter 408 and includes electromagnetic lenses, deflectors, and apertures. Electromagnetic lenses are used to focus the individual electron beams to a fine point on a surface of the semiconductor device 34. These lenses generate magnetic fields that bend and shape the paths of the electrons, allowing precise control over the beam's focus and convergence. In addition to focusing the beams, the optics system ensures that the beams maintain consistent spacing and alignment across the wafer. Deflectors (not shown) within the system are responsible for guiding the beams along specific trajectories, enabling them to scan designated areas of the wafer in a controlled and coordinated manner.

The apertures and deflectors in an electron multi-beam inspection system 402 are important for dividing and controlling the electron beams, ensuring precise scanning and inspection of the wafer surface. These components are designed to manage the trajectories and focus of each beam as they pass through the system. According to some embodiments, microelectromechanical systems (MEMS) technology is employed to create highly precise and controllable apertures and deflectors, enabling superior beam manipulation.

Apertures serve as beam-shaping elements, selectively allowing portions of the electron beam to pass through while blocking the rest. Such apertures are arranged in a well-defined grid or array that splits the primary electron beam into multiple smaller beams. MEMS-based apertures are particularly effective due to their small size, precise manufacturing, and ability to maintain high accuracy in positioning. These MEMS apertures can be fabricated from materials such as silicon, which provides both structural integrity and the ability to interact with electron beams effectively.

Deflectors, which guide the paths of the individual beams, are often electrostatic or electromagnetic, using controlled electric or magnetic fields to manipulate the direction of the electrons. MEMS-based deflectors take advantage of micro-scale actuators that adjust the beam paths with a high degree of precision. By modulating the voltage or current applied to these MEMS deflectors, the system can dynamically alter the angle and position of the beams, ensuring accurate scanning of the wafer surface.

According to some embodiments, the focusing device 412 includes a variable condenser lens located between the electron source 404 and the beam splitter 408. In other embodiments, the focusing device 412 further includes a non-variable condenser lens (not shown) located between the electron source 404 and the variable condenser lens 412. A variable condenser lens 412 is an adjustable optical component used in electron beam systems, including electron multi-beam inspection systems, to control and focus the electron beams onto the target surface, such as a semiconductor wafer. The function of the condenser lens is to shape and condense the electron beams into a fine, focused spot, ensuring that the beams maintain the desired intensity and resolution during inspection or imaging.

The term “variable” refers to the lens's ability to adjust the focal properties dynamically, allowing operators to modify the electron beam characteristics in real-time. This adjustability is achieved by varying the strength of the electromagnetic field generated by the lens in some embodiments. A variable condenser lens 412 uses electromagnetic coils to produce a magnetic field through which the electron beam passes. By controlling the current applied to these coils, the strength of the magnetic field is altered, which in turn affects the focusing power of the lens. Increasing the current strengthens the field and tightens the beam's focus while reducing the current broadens the focus.

One of the advantages of a variable condenser lens 412 is its ability to accommodate different operational requirements. For example, during low-magnification imaging, the lens can be adjusted to focus the beams over a wider area, allowing for faster scanning and coverage. For high-resolution imaging, the lens can be tuned to provide a tighter focus, enabling the system to capture detailed features on the wafer with greater accuracy. This flexibility is particularly beneficial in semiconductor device inspection, where different stages of the process may require varying levels of resolution and precision.

FIG. 3A is a top view of a beam splitter 300a configured as an aperture array, according to various embodiments. In this embodiment, the beam splitter 300a is an aperture array that includes a plurality of reconfigurable apertures 502. According to various embodiments, the beam splitter 300a includes a plurality of MEMS actuators (not shown) that are configured to dynamically control the plurality of apertures 502 individually. The aperture array is configured so that a blocking area is formed by a plurality of closed apertures 502 and an open area is formed by a plurality of open apertures 502. A region of interest 504, which defines a semiconductor device circuit feature that is to be inspected, is superimposed over the aperture array (i.e., to show a relative position of the circuit feature and the beam splitter 300a). The lower portion of FIG. 3A schematically shows a scanning path 506 of an individual sub-beam 410. As shown, the region of interest 504 has an area that is considerably smaller than a total area of the beam splitter 300a. As such, sub-beams 410 passing through apertures 502 that do not overlap with the region of interest 504 tend to produce signals that are irrelevant to the circuit feature to be scanned.

FIG. 3B is a top view of a mask 300b having a blocking area 508 and an open area 510, according to various embodiments. The mask 300b includes a blocking area 508 configured to block a first plurality of the sub-beams 410 and an open area 510 configured to allow a second plurality of the sub-beams 410 to pass through the mask 300b. As shown, the open area 510 has a shape corresponding to a region of interest 504 on a wafer (e.g., semiconductor device 34) located below the mask 300b. The use of the mask 300b improves throughput of the electron-beam inspection system 402 by removing sub-beams 410 that would be otherwise irrelevant (i.e., that are not directed to the region of interest 504). In this regard, unwanted signals 413 are reduced by blocking a first plurality of sub-beams 410 that are not relevant to the features that are being inspected (i.e., features corresponding to a shape of the region of interest 504). Thus, the throughput is increased by only considering signals 413 generated by a second plurality of sub-beams 410 that are allowed to pass through the open area 510 of the mask 300b. However, the electron beam current in the second plurality of sub-beams 410 that are allowed to pass through the open area 510 of the mask 300b is less than it would be if the primary electron beam 406 could be more tightly focused, as described in greater detail with reference to FIGS. 4A to 4C, below

FIGS. 4A to 4C are top views of beam splitters (400a, 400b, 400c) each with a focused electron beam impinging on an optimized beam illumination area (602a, 602b, 602c), according to various embodiments. As shown, in each of FIGS. 4A to 4C, the optimized beam illumination area (602a, 602b, 602c) is smaller (e.g., see arrows) than a total area of the respective beam splitter (400a, 400b, 400c). As described above, the focusing device 412 (e.g., a variable condenser lens) generates the optimized beam illumination area (602a, 602b, 602c) from the primary electron beam 406. Also as shown, in each case, the optimized beam illumination area (602a, 602b, 602c) is chosen to have an area that closely surrounds the region of interest 504. As such, only apertures 502 (e.g., see FIG. 3A) within the optimized beam illumination area (602a, 602b, 602c) will generate sub-beams 410. As such, sub-beams 410 outside of the optimized beam illumination area (602a, 602b, 602c) are not generated. In this way, each of the sub-beams 410 that are generated within the optimized beam illumination area (602a, 602b, 602c) each have a greater beam current than would otherwise be generated if the primary electron beam 406 was not so tightly focused.

According to various embodiments, the electron-beam inspection system 402 combines a mask 300b with a primary electron beam 406 that is focused to form an optimized beam illumination area (602a, 602b, 602c). In this way, throughput is improved by increasing electron current in the sub-beams 410 that are generated by the focused electron beam having the optimized beam illumination area (602a, 602b, 602c). Further, the mask 300b is configured such that the open area 510 of the mask is located within an optimized sub-area of the beam splitter (i.e., a sub-area corresponding to the optimized beam illumination area (602a, 602b, 602c)). Various types of masks 300b are used in respective embodiments. For example, in some embodiments, the mask 300b has a fixed configuration with a fixed blocking area 508 and a fixed open area 510. In other embodiments, the mask 300b is configured based on a reconfigurable shutter system in which the blocking area 508 and the open area 510 are reconfigurable, as described in greater detail with reference to FIGS. 5A and 5B, below.

FIGS. 5A and 5B are top views of a mask 500 having a reconfigurable shutter system in a first configuration (FIG. 5A) and a second configuration (FIG. 5B), according to various embodiments. According to various embodiments, the mask 500 includes a plurality of reconfigurable shutters 702 (e.g., MEMS shutters) that are configured to dynamically control a size and shape of the blocking area 508 and the open area 510. As shown in FIG. 5A, the reconfigurable shutters 702 allow various shapes of the blocking area 508 and the open area 510 to be defined. For example, as shown in FIG. 5B, the plurality of reconfigurable shutters 702 are opened to define an open area 510 having a shape corresponding to the region of interest 504.

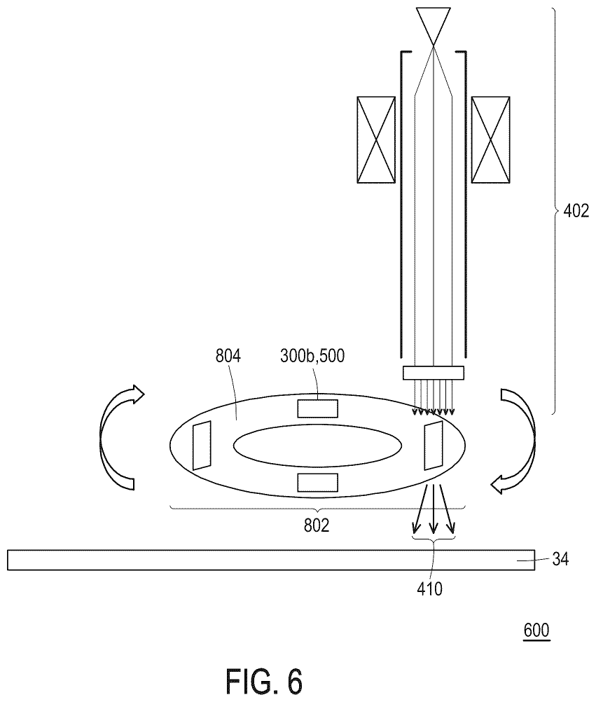

FIG. 6 is a vertical cross-sectional view of an electron-beam inspection system 600 including a reconfigurable multi-mask device 802 having a plurality of selectable masks (300b, 500), according to various embodiments. The reconfigurable multi-mask device 802 includes a positioning device 804 configured to position a selected mask 500 between the beam splitter (408, 300a, 400a, 400b, 400c) and the semiconductor device 34. In this regard, the semiconductor device 34 is held by a stage 360 (e.g., see FIG. 2) that positions the semiconductor device 34 relative to the positioning device 804. The reconfigurable multi-mask device 802 allows various masks (300b, 500) to be dynamically selected depending on various circuit patterns on the semiconductor device 34 that are to be inspected. In the embodiment of the FIG. 6, the positioning device 804 is configured as a rotatable stage that rotates to move a selected mask (300b, 500) into position. However, the disclosed embodiments are not so limited, and various other configurations of the 804 are implemented in other embodiments. According to various embodiments, the above-described electron-beam inspection system 402 is integrated with a lithography system 100, as described in greater detail below. In other embodiments, the electron-beam inspection system 402 is separate and distinct from the lithography system 100.

Referring to all drawings and according to various embodiments of the present disclosure, electron-beam inspection system 402 is provided. The electron-beam inspection system 402 includes an electron source 404, a focusing device 412, configured to generate a focused primary electron beam 406 having an optimized beam illumination area (602a, 602b, 602c), a beam splitter 408 having an area that is larger than the optimized beam illumination area (602a, 602b, 602c), and a reconfigurable multi-mask device 802 including a plurality of selectable masks 500.

According to various embodiments, the electron-beam inspection system 402 further includes a mask (300b, 500) having a blocking area 508 and an open area 510. According to various embodiments, the open area 510 is located within the optimized beam illumination area (602a, 602b, 602c). According to various embodiments, the mask 500 includes a plurality of MEMS shutters 702 that are configured to dynamically control a size and shape of the blocking area 508 and the open area 510. According to various embodiments, the open area 510 of the mask (300b, 500) has a shape corresponding to a region of interest 504 of a circuit pattern of the substrate (10, 210). According to various embodiments, the mask (300b, 500) is one of the plurality of selectable masks (300b, 500) of the reconfigurable multi-mask device 802. According to various embodiments, the electron-beam inspection system 402 further includes a positioning device 804 configured to position a selected mask (300b, 500) between the beam splitter 408 and a substrate holder 360.

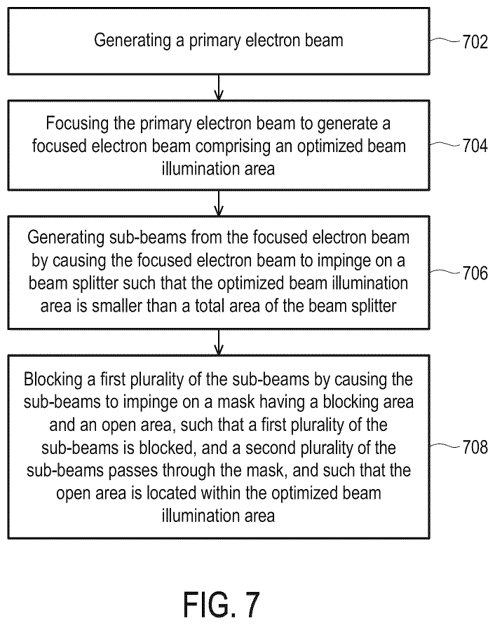

FIG. 7 is a flowchart illustrating operations of a method 700 of performing an electron multi-beam inspection of a semiconductor substrate (10, 210), according to various embodiments. In operation 702, the method 700 includes generating a primary electron beam 406. In operation 704, the method 700 includes focusing the primary electron beam 406 to generate a focused electron beam 406 including an optimized beam illumination area (602a, 602b, 602c). In operation 706, the method 700 includes generating sub-beams 410 from the focused electron beam 406 by causing the focused electron to beam 406 to impinge on a beam splitter (408, 300a, 400a, 400b, 400c) such that the optimized beam illumination area (602a, 602b, 602c) is smaller than a total area of the beam splitter (408, 300a, 400a, 400b, 400c).

In operation 708, the method 700 includes blocking a first plurality of the sub-beams 410 by causing the sub-beams 410 to impinge on a mask (300b, 500) including a blocking area 508 and an open area 510, such that a first plurality of the sub-beams is blocked, and a second plurality of the sub-beams passes through the mask, wherein the open area 510 is located within the optimized beam illumination area (602a, 602b, 602c). According to various embodiments, the mask (300b, 500) includes a plurality of MEMS shutters 702. The method 700 further includes dynamically controlling a size and shape of the blocking area 508 and the open area 510 by controlling the plurality of MEMS shutters 702 such that the open area 510 of the mask (300b, 500) corresponds to a region of interest 504 of a circuit pattern of the semiconductor substrate (10, 210).

According to various embodiments, the mask (300b, 500) is one of a plurality of selectable masks (300b, 500) of a reconfigurable multi-mask device 802. In such embodiments, the method 700 further includes controlling a positioning device 804 of the reconfigurable multi-mask device 802 to select the mask (300b, 500) from the plurality of selectable masks (300b, 500) and to position the mask (300b, 500) between the beam splitter (408, 300a, 400a, 400b, 400c) and a substrate holder 360.

Disclosed embodiments are advantageous by providing systems (100, 402) and methods 700 of performing electron multi-beam inspection of a semiconductor substrate (10, 210) with increased signal quality and throughput. In this regard, a method 700 includes focusing a primary electron beam 406 to generate a focused electron beam 406 having an optimized beam illumination area (602a, 602b, 602c). The focused electron beam 406 is then caused to impinge on a beam splitter (300a, 400a, 400b, 400c, 500) such that the optimized beam illumination area (602a, 602b, 602c) is smaller than a total area of the beam splitter (300a, 400a, 400b, 400c). As such, electron sub-beams 410 generated by the beam splitter (300a, 400a, 400b, 400c) are directed only into areas tightly surrounding a region of interest 504 corresponding to a circuit element to be scanned. The electron current in individual sub-beams 410 is thereby increased by focusing the optimized electron beam 406 in this way. A mask (300b, 500) is also used to block sub-beams 410 from regions other than the region of interest 504. This blocking reduces unwanted signals from areas outside of the region of interest 504 and thereby increases the throughput of electron multi-beam inspection systems 402.

According to various embodiments, an electron-beam inspection system includes an electron source configured to generate a primary electron beam, a beam splitter configured to generate sub-beams from the primary electron beam, a focusing device configured to focus the primary electron beam on an optimized sub-area of the beam splitter, wherein the optimized sub-area is smaller than a total area of the beam splitter, and a mask including a blocking area configured to block a first plurality of the sub-beams and an open area configured to allow a second plurality of the sub-beams to pass through the mask. According to various embodiments, the focusing device includes a variable condenser lens located between the electron source and the beam splitter. According to various embodiments, the focusing device further includes a non-variable condenser lens located between the electron source and the variable condenser lens.

According to various embodiments, the beam splitter is an aperture array including a plurality of apertures such that the blocking area includes closed apertures and the open area includes open apertures. According to various embodiments, the beam splitter includes a plurality of microelectromechanical (MEMS) shutters that are configured to be dynamically controlled. According to various embodiments, the open area of the mask is located within the optimized sub-area of the beam splitter. According to various embodiments, the open area of the mask has a shape corresponding to a region of interest on a wafer located below the mask. According to various embodiments, the mask includes a fixed blocking area and a fixed open area.

According to various embodiments, the electron-beam inspection system further includes a reconfigurable multi-mask device including a plurality of selectable masks, and the mask is one of the plurality of selectable masks of the reconfigurable multi-mask device. According to various embodiments, the mask includes a reconfigurable shutter system in which the blocking area and the open area are reconfigurable. According to various embodiments, the reconfigurable shutter system includes a plurality of MEMS shutters that are configured to dynamically control a size and shape of the blocking area and the open area. In other embodiments, the shutters need not be MEMS shutters but are configured as mechanical components fabricated by other methods.

According to various embodiments, an electron-beam inspection system includes an electron source, a focusing device configured to generate a primary electron beam including an optimized beam illumination area, a beam splitter including an area that is larger than the optimized beam illumination area, and a reconfigurable multi-mask device comprising a plurality of selectable masks. According to various embodiments, the electron-beam inspection system further includes a mask having a blocking area and an open area, wherein the open area is located within the optimized beam illumination area. According to various embodiments, the mask includes a plurality of MEMS shutters that are configured to dynamically control a size and shape of the blocking area and the open area. According to various embodiments, the open area of the mask has a shape corresponding to a region of interest of a circuit pattern of the substrate. According to various embodiments, the mask is one of the plurality of selectable masks of the reconfigurable multi-mask device. According to various embodiments, the electron-beam inspection system further includes a positioning device configured to position a selected mask between the beam splitter and the substrate holder.

According to various embodiments, a method of performing an electron multi-beam inspection of a semiconductor substrate includes generating a primary electron beam; focusing the primary electron beam to generate a focused electron beam including an optimized beam illumination area; generating sub-beams from the focused electron beam by causing the focused electron beam to impinge on a beam splitter such that the optimized beam illumination area is smaller than a total area of the beam splitter; and blocking a first plurality of the sub-beams by causing the sub-beams to impinge on a mask including a blocking area and an open area, such that a second plurality of the sub-beams passes through the mask, wherein the open area is located within the optimized beam illumination area.

According to various embodiments, the mask includes a plurality of MEMS shutters, and the method further includes dynamically controlling a size and shape of the blocking area and the open area by controlling the plurality of MEMS shutters such that the open area of the mask corresponds to a region of interest of a circuit pattern of the semiconductor substrate. According to various embodiments, the mask is one of a plurality of selectable masks of a reconfigurable multi-mask device, and the method further includes controlling a positioning device of the reconfigurable multi-mask device to select the mask from the plurality of selectable masks and to position the mask between the beam splitter and a substrate holder.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure and that they may make various changes, substitutions, and alterations herein without departing from the spirit and scope of the present disclosure.

What is claimed is:

1. An electron-beam inspection system, comprising:
an electron source configured to generate a primary electron beam;
a beam splitter configured to generate sub-beams from the primary electron beam;
a focusing device configured to focus the primary electron beam on an optimized sub-area of the beam splitter, wherein the optimized sub-area is smaller than a total area of the beam splitter; and
a mask comprising a blocking area configured to block a first plurality of the sub-beams and an open area configured to allow a second plurality of the sub-beams to pass through the mask.

2. The electron-beam inspection system of claim 1, wherein the focusing device comprises a variable condenser lens located between the electron source and the beam splitter.

3. The electron-beam inspection system of claim 2, wherein the focusing device further comprises a non-variable condenser lens located between the electron source and the variable condenser lens.

4. The electron-beam inspection system of claim 1, wherein the beam splitter is an aperture array comprising a plurality of apertures such that the blocking area comprises closed apertures and the open area comprises open apertures.

5. The electron-beam inspection system of claim 4, wherein the beam splitter comprises a plurality of microelectromechanical (MEMS) shutters that are configured to be dynamically controlled.

6. The electron-beam inspection system of claim 4, wherein the open area of the mask is located within the optimized sub-area of the beam splitter.

7. The electron-beam inspection system of claim 6, wherein the open area of the mask comprises a shape corresponding to a region of interest on a wafer located below the mask.

8. The electron-beam inspection system of claim 1, wherein the blocking area is a fixed blocking area and the open area is a fixed open area.

9. The electron-beam inspection system of claim 1, further comprising:
a reconfigurable multi-mask device comprising a plurality of selectable masks,
wherein the mask is one of the plurality of selectable masks of the reconfigurable multi-mask device.

10. The electron-beam inspection system of claim 1, wherein the mask comprises a reconfigurable shutter system in which the blocking area and the open area are reconfigurable.

11. The electron-beam inspection system of claim 10, wherein the reconfigurable shutter system comprises a plurality of MEMS shutters that are configured to dynamically control a size and shape of the blocking area and the open area.

12. An electron-beam inspection system, comprising:
an electron source;
a focusing device configured to generate a primary electron beam comprising an optimized beam illumination area;
a beam splitter comprising an area that is larger than the optimized beam illumination area; and
a reconfigurable multi-mask device comprising a plurality of selectable masks.

13. The electron-beam inspection system of claim 12, further comprising:
a mask comprising a blocking area and an open area, wherein the open area is located within the optimized beam illumination area.

14. The electron-beam inspection system of claim 13, wherein the mask comprises a plurality of MEMS shutters that are configured to dynamically control a size and shape of the blocking area and the open area.

15. The electron-beam inspection system of claim 13, wherein the open area of the mask comprises a shape corresponding to a region of interest of a circuit pattern of a substrate.

16. The electron-beam inspection system of claim 13, wherein the mask is one of the plurality of selectable masks of the reconfigurable multi-mask device.

17. The electron-beam inspection system of claim 16, further comprising:
a positioning device configured to position a selected mask between the beam splitter and a substrate holder.

18. A method of performing an electron multi-beam inspection of a semiconductor substrate, comprising:
generating a primary electron beam;
focusing the primary electron beam to generate a focused electron beam comprising an optimized beam illumination area;
generating sub-beams from the focused electron beam by causing the focused electron beam to impinge on a beam splitter such that the optimized beam illumination area is smaller than a total area of the beam splitter; and
blocking a first plurality of the sub-beams by causing the sub-beams to impinge on a mask comprising a blocking area and an open area, such that a second plurality of the sub-beams passes through the mask, wherein the open area is located within the optimized beam illumination area.

19. The method of claim 18, wherein the mask comprises a plurality of MEMS shutters, the method further comprising:
dynamically controlling a size and shape of the blocking area and the open area by controlling the plurality of MEMS shutters such that the open area of the mask corresponds to a region of interest of a circuit pattern of the semiconductor substrate.

20. The method of claim 18, wherein the mask is one of a plurality of selectable masks of a reconfigurable multi-mask device, the method further comprising:
controlling a positioning device of the reconfigurable multi-mask device to select the mask from the plurality of selectable masks and to position the mask between the beam splitter and a substrate holder.
